(19) United States
(12) Patent Application Publication
(10) Pub. No.: US 2006/0234062 A1
(43) Pub. Date: Oct. 19, 2006

(54) Method for grafting a chemical compound to a support substrate

(75) Inventors: Hans-Peter Brack, HERRLIBERG (CH); Celestino Padeste, Baden (CH); Michal Slaski, Ruefenach (CH); Harun Solak, Brugg (CH)

Correspondence Address: SIEMENS SCHWEIZ AG;I-47, INTELLECTUAL PROPERTY, ALBISRIEDERSTRASSE 245, ZURICH, CH-8047, CH

(73) Assignee: PAUL SCHERRER INSTITUT

(21) Appl. No.: 10/563,112

(22) PCT Filed: Jun. 12, 2004
(86) PCT No.: PCT/EP04/06362

§ 371 Date: Jan. 3, 2006

(30) Foreign Application Priority Data
Jul. 24, 2003 (EP) 03016889.2

(51) Int. Cl. B05D 3/00; G11B 5/64; C23C 16/00; B32B 27/00; B32B 27/30

(52) U.S. Cl. 428/421; 427/532; 427/248.1; 428/422; 428/523; 428/141; 428/522; 428/500

(57) ABSTRACT

According to the present invention a method for grafting a chemical compound to a predetermined region of a support substrate (4) is disclosed, comprising: a) irradiating selectively the support substrate with electromagnetic radiation and/or particle radiation in order to both define said predetermined region and to form at least one reactive functional group or a precursor thereof in said predetermined region of the support substrate; b) exposing the irradiated support substrate to said chemical compound or to a precursor thereof. Therefore, only these very few steps are needed to effectively grafting the desired chemical compound, such as an organic compound, to the predetermined regions of the support substrate. Moreover, the irradiation step can be carried out in a vastly flexible manner and allows to generate numerous distinct shapes of the predetermined regions. Further, micro- or nano-scale regions in the support substrate capable of forming reactive functional groups or precursors thereof upon exposure to particle or electromagnetic irradiation can be easily achieved.

The invention relates to a method for grafting a chemical compound to a predetermined region of a support substrate.

Rapid and simple methods for creating micro- and nano-structured surfaces or three-dimensional structures, such as tubes or channels, in the support substrate are desirable. These micro- and nano-structured surfaces or three-dimensional structures have designed features, structures or aspects with lateral or vertical dimensions on the order of from one nanometer to several microns. To allow these structures a broad field of applications, it is desired that these micro- and nano-structured surfaces can be made having a wide variety of chemical functionalities and physical properties. Properties of interest include reactivity or binding characteristics towards particular chemical species or hydrophobic or hydrophilic properties. It is further desirable to be able to create these structures having these functionalities or properties structured in the form of nano- or micro-scale arrays or other geometric structures. For example, such micro- and nano-structured materials can find application in combinatorial chemistry, (bio)-sensing, membrane technologies, lithography, printing, liquid repellents, adhesives, lubricants, anti-fogging coatings, and micro- and nano-electronic, opto-electronic and magnetic devices. Alternatively, they can be used to create biologically compatible surfaces or to offer medical or bio-technological active surfaces.

One form of such suitable materials are known as “polymer brushes”, and they are described, for example, by Freemantle in Chemical & Engineering News, Apr. 14, 2003, p. 41-45. In these materials polymer chains are tethered at one end, usually by covalent bonding, to a surface or an interface. Such polymer brushes can be made by the “grafting-to” or “grafting-from” methods. The grafting-to method involves the reaction of preformed polymer chains with a surface to anchor the chains on the surface. The grafting-to method has the disadvantage of giving surfaces with only low grafting densities (number of polymer chains/unit area). In particular, polymer chains at the interface of a solution and substrate are in the form of brushes only if the grafting density is high enough to force the chains to adopt elongated rather than coiled conformations.

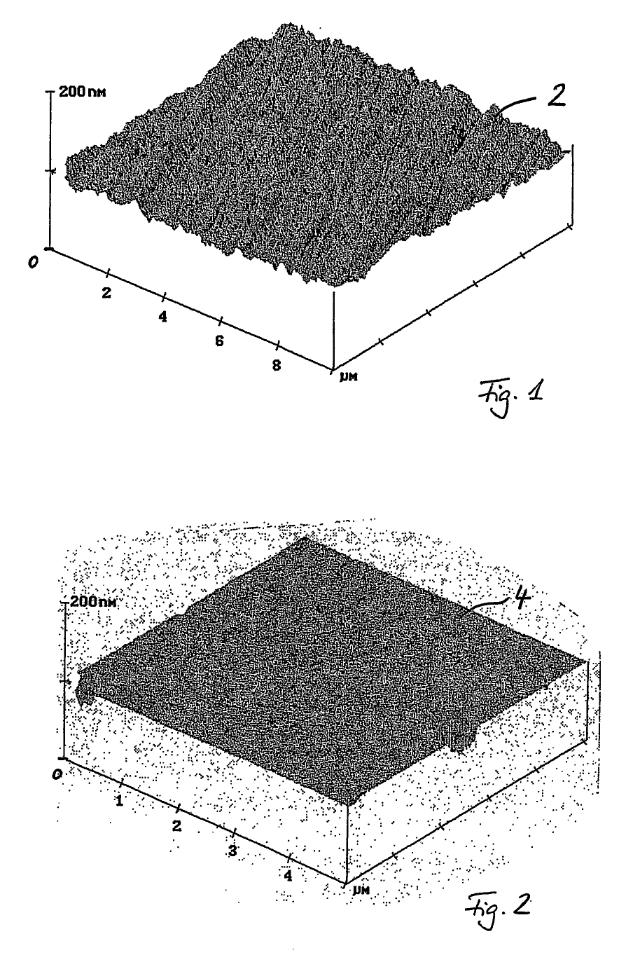

In the grafting-from method, initiator molecules are immobilized on a surface and exposed to a monomer under appropriate polymerization conditions. The grafting-from method currently suffers from the disadvantages of requiring multiple steps for creating, activating, and reacting initiator sites, and they are typically created only on comparably expensive special gold or silicon surfaces. An example of such a reaction scheme is disclosed from U. Schmelmer and co-workers in Angew. Chem. Int. Ed. 42, No. 5 (2003) 559-563, especially in FIG. 1 of this disclosure.

In view of the several afore mentioned drawbacks of the actually known methods, it would be a desired aim of the invention to have simpler methods involving less preparation steps and common and inexpensive reagents, processes, and substrates. In particular, it would be desirable to be able to use common polymers as flexible and extrudable, moldable or castable substrates.

This aim is achieved according to the present invention by a method for grafting a chemical compound to a predetermined region of a support substrate, comprising:
a) irradiating selectively the support substrate with electromagnetic radiation and/or particle radiation in order to both define said predetermined region and to form at least one reactive functional group or a precursor thereof in said predetermined region of the support substrate;
b) exposing the irradiated support substrate to said chemical compound or to a precursor thereof.

Therefore, only these very few steps are needed to effectively grafting the desired chemical element or compound, such as an organic compound, to the predetermined regions of the support substrate. Moreover, the irradiation step can be carried out in a vastly flexible manner and allows to generate numerous distinct shapes of the predetermined regions. Further, micro- or nano-scale regions in the support substrate capable of forming reactive functional groups or precursor thereof upon exposure to particle or electromagnetic irradiation can be easily achieved. Thereby, in view of the above mentioned invention, a reactive functional group is considered as being any modified structural unit generated by the irradiating step that is able to act as a reactive site for the chemical compound to be grafted thereupon.

The step of exposing can be a simultaneous or subsequent step, when the irradiated support substrate is exposed preferably to one or more radically polymerizable monomer species. The physical properties, height, penetration depth and spatial resolution of the micro- or nano-scale modification of the support substrate can be conveniently varied by controlling the various parameters in the irradiation or exposing steps. There is no specific limitation as to the substrate depth that is modified. The modification can be primarily just on the surface or extend through the entire thickness of the substrate. Examples of these parameters in the irradiation process include the type and energy of the radiation, the total dose, the dose rate and the irradiation atmosphere.

With respect to the type of the support substrate used in this invention there does not exist any specific limitations. Any organic or inorganic substrate capable of forming reactive functional groups upon exposure to ionizing irradiation are suitable. The composition and chemical structure of the substrate is also not limited. The substrate will generally be selected according to the desired properties for the substrate, for example, mechanical properties, or according to the desired properties for the non-structured regions such as hydrophilic or hydrophobic or reactive or inert. Some non-limiting examples of substrates include polymers such as fluoropolymers like PTFE, FEP, PVDF or ETFE or polyolefins like polyethylene or polypropylene. Additionally, even the form of the substrate is not specifically limited and includes coatings, films, and shaped particles.

With respect to the reactive functional group dealing as the receptor nuclei for the latter grafting a non-limiting number of examples for the reactive functional groups introduced by the irradiation can be mentioned. These examples include hydroperoxides, peroxides or such radical species as alkyl, oxy, or peroxy radicals.

Referring to the type of radiation used to generate the reactive functional groups in this invention again no reasonable specific limitation is in sight. Radiation may include electromagnetic radiation like UV or X-rays or particle radiation such as electron beam. In particular, the irradiation energy and type can be varied to control the depth of functionalization of the latter micro- or nano-grafting into the support substrate. For example, the wavelength of the electromagnetic radiation or accelerating potential for the electron beam will have a strong influence on the penetration depth as it can be derived from physical penetration theory. The wavelength also determines the minimum spatial resolution in patterning. The total dose and dose rate influence the total number and thus density of reactive sites (reactive functional groups) formed.

Furthermore, the irradiation atmosphere can be controlled to yield oxygen-containing or other element-containing reactive sites in the substrate. In some cases a vacuum or inert irradiation atmosphere might be selected in order to minimize degradation of the support substrate. In the case of polymeric substrates, the irradiation conditions can be selected in order to preferentially bring about crosslinking or chain scission or even ablation of the polymer substrate.

However, masks or stencils and interference or projection lithography or other methods known in the prior art can be used to create the micro- or nano-scale pattern of reactive sites on and/or in the support substrate.

The method used to micro- or nano-graft the substrate is not specifically limited. For example, the grafting can be carried out simultaneously along with the irradiation process, or the grafting can be done in a post-irradiation step. If the grafting is done in a subsequent step, the irradiated substrate may be stored at room temperature or at reduced or at elevated temperature and/or under inert atmosphere if the reactive sites are unstable.

Parameters in the grafting process can be varied in order to optimize the resolution of the grafting process. For example, the sharpness and height of the grafted micro- or nano-regions can be enhanced or controlled by proper selection of the monomer concentration or grafting temperature. Other parameters such as the choice of solvent or the use of chain-transfer or terminating agents or living polymerization agents or methods can also be used to influence these properties.

The physical form of the monomer is also not specifically limited in this invention. For example, the monomer may be applied to the substrate in the form of a gas or a liquid, and the monomer may be either pure or diluted with a solvent or inert material and/or as a mixture with one or more additional monomers. Any radically active monomer may be used in this invention including vinyl, styrenic or acrylic monomers. Monomers can be selected in this invention according to the properties that are desired for the micro- or nano-structured grafted regions. For example, if it is desired that the grafted region be hydrophilic in nature, monomers having polar or hydrogen bonding functional groups such as amine, amide, thiol, hydroxy, carboxyl, carboxylic acid, or ester may be selected. Further non-limiting examples of hydrophilic monomers include acrylic acid and its salts, methacrylic acid and its salts, methyl methacrylate, sulfonated styrene and its salts, styrene sulfonic acid and its salts, or vinyl sulfonic acid. If the grafted regions should be hydrophobic, fluorinated or hydrocarbon monomers can be used. Non-limiting examples include styrene, ethylene, propylene, and tetrafluoroethylene. If it is desired that the grafted regions should be electronically conducting or semi-conducting, the monomeric, oligomeric or pre-poylmerised form of conducting or semi-conducting polymers, or the monomeric, oligomeric or pre-poylmerised form of polymers that are precursors to conducting or semi-conducting polymers can be used. Non-limiting examples of monomers include vinyl aniline, vinyl pyrrole, glycidyl methacrylate, 5-vinyl-2,2′:5′,2″-terthiophene, 3-vinyl perylene, and vinyl carbazole. In another embodiment of the current invention, monomers having specific functional groups useful for binding or sensing of target species are used. In yet another embodiment one or more monomers may be selected in order to combine the properties of conductivity and binding or sensing of target species.

The modified grafted regions in the support substrates are characterized in that they are micro- or nano-scale regions, either substantially 2-dimensional or 3-dimensional, that contain the grafted polymer chains. There is no specific limitation on the shape or form of these grafted regions, and for example, they may be lines, dots, grids, mesh, stenciled, channels, tubes, cylinders or any other suitable arbitrary geometric shapes. These grafted regions may be either nano- or micrometer scale in height. With reference to the afore mentioned 3-dimensional shape, the grafted regions may also penetrate into the interior of the modified material and/or may be detached from the surface in a subsequent step. The grafted regions may be used to define or create conduction or flow pathways and patterns for electrons, ions, chemical species, and fluids. In this manner, the grafted regions can be used for the generation of electronic circuits. In one embodiment, the pattern of grafted regions may be used to generate patterns in other materials. Non-limiting examples include printing, soft lithography, and transfer techniques.

Without any limitation to any application a person skilled in the art may have apparently understood from the description, the application of these micro- or nano-grafted materials is proposed for use in the fields of combinatorial chemistry, membrane technology, surface science (including repellents, adhesives and lubricants and anti-fogging and other coatings), sensing, information storage, lithography, printing, chromatography, separation processes, electrochemical synthesis, medical and bio-technical material handling, electrochemical energy storage and conversion devices, and microfluidic, electronic, opto-electronic and magnetic devices. A person skilled in the art will be able to select substrates, chemical elements or compounds, and predetermined regions appropriate for any of these applications. A non-limiting example is a micro- or nano-grafted material modified through its thickness with functional groups useful for the conduction of ions or other species. Non-limiting examples of such functional groups include acids, bases, or amphoteric groups.

The various features and advantages of this invention will become apparent to those skilled in the art from the following detailed description of the currently preferred embodiment. The drawings that accompany the detailed description can be briefly described as follows:

FIG. 1 is a 100 μm ETFE-film as received;

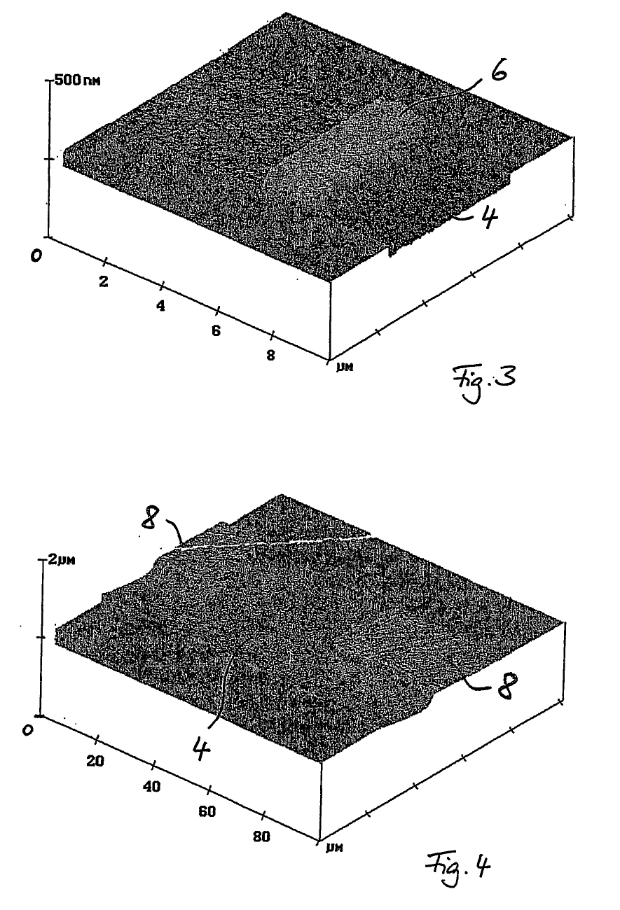

FIG. 2 is a 100 μm ETFE-film, flattened at 230° C.;

FIG. 3 is a 100 μm ETFE-film, flattened at 230° C., electron beam exposed (line ″1a) and grafted with 10% acrylic acid for 20 min;

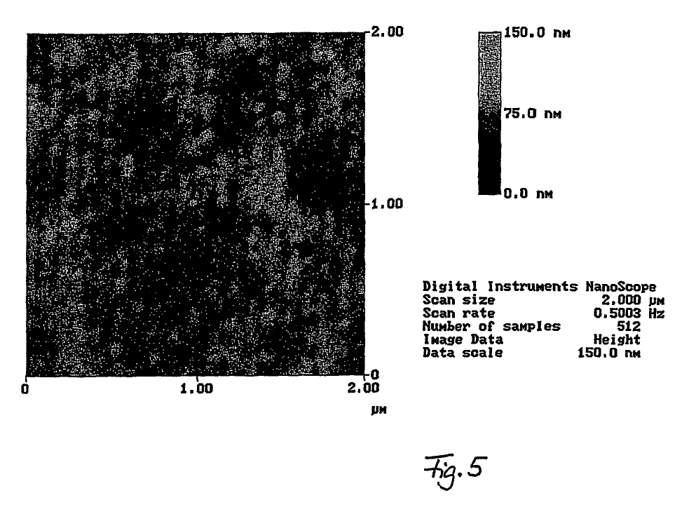

FIG. 4 is a 100 μm ETFE film, flattened at 230° C., X-ray exposed (exposure 1, box 1) and grafted with 5% acrylic acid; and

FIG. 5 is a 100 μm ETFE-film, flattened at 230° C., X-ray exposed (interference set-up, period: 100 nm) and grafted with 5% acrylic acid for 15 min at 50° C.

For the examples, Nowoflon ET-6235 films having thicknesses of 25, 50, and 100 μm and extruded roll widths of 155 cm designated here as N-25, N-50, N-100 were purchased from Nowofol GmbH, Siegsdorf, Germany. The average molar weight of the Dyneon ET 6235 copolymer used to make these films is approximately 400,000 Dalton.

To obtain a flat test surface, a piece of ETFE film 2 (Nowoflon ET-6235, 100 μm, “N-100”) was placed between two polished 4″ silicon wafers, or 2.5×2.5 cm² pieces thereof. In a hot press which is optimised for nano-imprint lithography, this sandwich was heated for 5′ at 230° C. under a pressure of 200-2500 N/cm². The procedure results in a reduction of film thickness of about 5-10%, and a drastic reduction in surface roughness as it can be seen from the comparison of the initial ETFE film 2 and the flattened ETFE film 4 in the FIGS. 1 and 2.

Electron beam exposures were done with a LION-LV1 e-beam system (Leica Microsystems, Jena, Germany). The beam energy was 2.5 keV. The “continuous path control” mode was used to obtain lines with the desired doses in our exposures. The beam defocus was adjusted to control the exposed linewidth.

X-ray exposures were done at the “X-ray Interference Lithography” beamline of the Swiss Light Source. The beamline uses undulator light with a central wavelength of 13.5 nm (92 eV) and approximately 2% spectral bandwidth. The incident x-ray power on the sample was several mW/cm² and the delivered dose was controlled with a fast beam shutter. A shadow mask in proximity to the sample to define the exposed areas on the sample. A TEM-grid with features in the range of ≧50 μm was used as a shadow mask in proximity to the sample to define the exposed areas in the sample. X-ray interference exposures were done as described by Harun Solak et al., Microelectronics Engineering 67-68 (2003) 56.62.

Pieces of micro- or nano-scale irradiated ETFE films were placed in small glass tube reactor equipped with purge gas inlets and outlets that can be sealed by means of stopcocks. The reactor is then filled with an aqueous solution of acrylic acid monomer and then closed. After purging the reactor for 1 hr with nitrogen, the reactor is sealed by first closing the outlet, and then the inlet. The reactor was then placed in a water bath preheated to the desired reaction temperature. When the reaction time is over, the reactor seal is broken and the sample is gently taken out of reactor. The sample was then rinsed four times with deionised water and then dried at room temperature.

The following reaction conditions were used:

| | Acrylic Acid | | Reaction |
|---|---|---|---|
| | conc./% | Temperature/° C. | Time/min |
| 1. | 10 | 60 | 20 |
| 2. | 5 | 60 | 20 |
| 3. | 5 | 50 | 15 |

The grafted samples were inspected in an optical microscope and characterized using atomic force microscopy (AFM). A Digital Instrument Nanoscope III (Dimension 3100) was used in the tapping mode using Nanosensor NCH type AFM tips with a resonance frequency of 330 kHz.

First measurements on e-beam exposed and grafted samples were conducted at the PSI as well as first characterization of X-ray exposed (shadow mask and interference set-up) and grafted samples.

FIG. 3 shows a typical AFM image of a line structure 6 produced by e-beam irradiation and grafting. The line width is depending on the defocus of the e-beam (which is not yet optimized for the used material) and on the dose supplied. Using the 10% acrylic acid solution to graft a sample exposed to low dose, a structure with a very sharp definition of the borders and a height in the range of 150 nm was obtained. Control measurements of a sample with the same e-beam exposure but without grafting showed no significant change in surface texture. In contrast, at high e-beam doses a significant milling of the surface was observed (data not shown.)

Flattened ETFE 4 was exposed to various doses of x-rays through a TEM grid used as a shadow mask. After grafting with 5% acrylic acid, the structures (≧50 μm) were clearly visible in the optical microscope. The height of the grafted structures 8 as measured with the AFM (FIG. 4) was in the range of 300 nm with very little dependence on the used dose of x-rays.

The AFM image (FIG. 5) of a sample which was irradiated in the x-ray interference set-up and grafted with 5% acrylic acid shows a pattern with a period of 100 nm.

The foregoing description is exemplary and not just a material specification. The invention has been described in an illustrative manner, and should be understood that the terminology used is intended to be in the nature of words of description rather than of limitation. Many modifications and variations of the present invention are possible in light of the above teachings. The preferred embodiment of this invention have been disclosed, however, one of ordinary skill in the art would recognize that certain modifications are within the scope of the invention. It is understood that within the scope of the appended claims, the invention may be practiced otherwise than as specifically described. For that reason, the following claims should be studied to determine the true scope and content of this invention.

1. Method for grafting a chemical compound to a predetermined region of a support substrate (4), comprising:
a) irradiating selectively the support substrate (4) with electromagnetic radiation and/or particle radiation in order to both define said predetermined region and to form a reactive functional group or a precursor thereof in said predetermined region of the support substrate;
b) exposing the irradiated support substrate to said chemical compound or to a precursor thereof.

2. Method according to claim 1, characterized in that
the step of exposing is carried out simultaneously during the step of irradiating.

3. Method according to claim 1, characterized in that
the step of exposing is carried out successively after the step of irradiating.

4. Method according to any of the preceding claims, characterized in that
the properties of the predetermined region are controlled in dependency of the parameters of the irradiating step.

5. Method according to claim 4, characterized in that
as properties of the predetermined region are considered at least one of the group comprising physical properties, chemical properties, height, penetration depth and spatial resolution.

6. Method according to claim 4 or 5, characterized in that
as parameter of the irradiating step are considered at least one of the group comprising type of radiation, energy of radiation, total dose of radiation and irradiation atmosphere.

7. Method according to any of the preceding claims, characterized in that
the support substrate (2) is chosen in the dependency of at least one property of the group containing desired reactive functional group or a precursor thereof, desired property of the support substrate and desired property of the non-irradiated regions.

8. Method according to claim 7, characterized in that
the support substrate is of organic or inorganic type and/or of reactive or inert type and/or hydrophilic or hydrophobic type.

9. Method according to any of the preceding claims, characterized in that
the reactive functional group is at least one selected from the group comprising hydroperoxides, peroxides, or any type of radicals such as alkyl radical, oxy radical and peroxy radical.

10. Method according to any of the preceding claims, characterized in that
UV or X-ray radiation is used as electromagnetical radiation.

11. Method according to claim 10, characterized in that
interference lithography is used to generate the predefined regions of reactive functional groups.

12. Method according to any of the preceding claims, characterized in that
electron beam is used as particle radiation.

13. Method according to any of the preceding claims, characterized in that
the compound or the predecessor of the compound is an organic monomer that is applied in form of a gas comprising the monomer or a liquid comprising the monomer to the predetermined region.

14. Method according to claim 13, characterized in that
the monomer is a radically active monomer.

15. Method according to claim 13 or 14, characterized in that
the monomer is used as a pure liquid or is diluted with a solvent or an inert material and/or a mixture with one or more additional monomers.

16. Method according to any of the preceding claims, characterized in that
the predetermined regions formed in the shape of a three dimensional tube or channel.

17. Method according to any of the preceding claims, characterized in that
the grafted material is detached from the support substrate or the support substrate is dissolved leading to free standing structures of the grafted material.

18. A micro- or nanostructured material prepared by the process of any of the claims 1 to 17.

19. A micro- or nanostructured material of claim 18, characterized in that
the substrate is a polymer and the compound is a polymer.

20. A micro- or nanostructured material of claim 18 or 19, characterized in that
the non-structured regions are hydrophobic and the modified grafted regions are hydrophilic.

21. A micro- or nanostructured material of claim 18 or 19, characterized in that
the non-structured regions are hydrophilic and the modified grafted regions are hydrophobic.

22. A micro- or nanostructured material of any of the preceding claims 18 to 21, characterized in that
the modified grafted regions comprises polymer brushes.

23. A micro- or nanostructured material of any of the preceding claims 18 to 22, characterized in that
the compound is selected from the group comprising acrylic, vinyl and styrenic polymers.

24. A micro- or nanostructured material according to any of the preceding claims 18 to 23 characterized in that
the compound is selected from the group comprising polyacrylic acid and its salts, polymethacrylic acid and its salts, polymethylmethacrylate, polystyrene, sulfonated polystyrene and its salts, polyethylene, polytetrafluoroethylene, and polypropylene.

25. A micro- or nanostructured material according to any of the claims 18 to 24, characterized in that
the compound has functional groups capable of selectively binding with chemical elements, functional groups or molecules present in a gaseous or liquid phase.

26. A micro- or nanostructured material according to any of the preceding claims 18 to 25, characterized in that
the compound has functional groups selected from the group comprising amine, amide, thiol, hydroxy, carboxyl, carboxylic acid, or ester functional groups.

27. A micro- or nanostructured material to any of the preceding claims 18 to 26, characterized in that
the substrate is modified through its entire thickness.

28. A micro- or nanostructured material of any of the preceding claims 18 to 27, characterized in that
a membrane is used for a separation, transport or conduction application.

29. A micro- or nanostructured material of claim 28, characterized in that
the membrane is used in an electrochemical cell.

30. A micro- or nanostructured material of any of the preceding claims 18 to 29, characterized in that
the substrate is a flexible polymer film.

31. A micro- or nanostructured material of claim 30, characterized in that
the polymer film is selected from the group comprising PTFE, FEP, ETFE, PVDF, PE, and PP.

32. The use of the micro- or nanostructured material of any of the preceding claims 18 to 31 in a combinatorial chemistry, biotechnological, or separation application.

33. A material comprising a polymer substrate having at least one region of grafted polymer,
wherein at least one lateral dimension of said region is between about 1 nanometer and about 5 micrometers.

34. A material as recited in claim 33, wherein said lateral dimension is between about 1 nanometer and about 1 micrometer.

35. A material as recited in claim 34, wherein said lateral dimension is between about 1 nanometer and about 500 nanometers.

36. A material comprising a polymer substrate having at least one region of grafted polymer,
wherein the height of said region is between about 1 nanometer and about 5 micrometers.

37. A material comprising a polymer substrate having at least one region of grafted polymer,
wherein the height of said region is between about 1 nanometer and about 1 micrometer.

38. A material comprising a polymer substrate having at least one region of grafted polymer,
wherein the height of said region is between about 1 nanometer and about 500 nanometers.

39. A material as recited in any of the preceding claims 33 to 38, wherein said regions are arranged in a periodic manner.

40. A material as recited in any of the preceding claims 33 to 39, wherein the shape of said regions is selected from the group consisting of dots, circles, polygons, or lines.

41. A material as recited in any of the preceding claims 33 to 40, wherein the form of said regions is a grid.

42. A material as recited in any of the preceding claims 33 to 41, wherein the substrate is flexible.

43. A material as recited in any of the preceding claims 33 to 42, wherein the substrate is extruded.

44. A material as recited in any of the preceding claims 33 to 43, wherein the substrate is a film.

45. A material as recited in any of the preceding claims 33 to 44, wherein the substrate is hydrophobic.

46. A material as recited in the preceding claim 45, wherein the substrate is a fluoropolymer.

47. A material as recited in any of the preceding claims 33 to 46, wherein the substrate is hydrophilic.

48. A material as recited in any of the preceding claims 33 to 47, wherein the grafted polymer is hydrophilic.

49. A material as recited in any of the preceding claims 33 to 48, wherein the grafted polymer is able to exchange ions.

50. A material as recited in any of the preceding claims 33 to 49, wherein the grafted polymer is hydrophobic.

51. A material as recited in any of the preceding claims 18 to 50, wherein the grafted polymer is conducting, semi-conducting, or photo-conducting.

52. A material as recited in the preceding claim 51, wherein the grafted polymer also has chemical sensing characteristics.

53. A process in which a material prepared by any of the processes, as recited in any of the preceding claims 18 to 52, is used to generate patterns in other materials.

54. A process in which any of the materials, as recited in any of the preceding claims 18 to 52, is used to generate patterns in other materials.
